(19) United States
(12) Patent Application Publication
(10) Pub. No.: US 2024/0274568 A1
(43) Pub. Date: Aug. 15, 2024

(54) PACKAGE FOR USE WITH INTEGARTED CIRCUIT

(71) Applicant: Renesas Electronics America Inc., Milpitas, CA (US)

(72) Inventors: Edgardo LABER, San Jose, CA (US); James Edwin VINSON, Palm Bay, FL (US)

(73) Assignee: Renesas Electronics America Inc., Milpitas, CA (US)

(21) Appl. No.: 18/496,612

(22) Filed: Oct. 27, 2023

Related U.S. Application Data
(60) Provisional application No. 63/484,297, filed on Feb. 10, 2023.

(51) Int. Cl. H01L 23/00; H01L 23/62; H02J 7/00

(52) U.S. Cl. CPC H01L 24/48; H01L 23/62; H01L 24/45; H02J 7/0029; H01L 23/498; H01L 2224/45124; H01L 2224/45144; H01L 2224/45147; H01L 2224/48091; H01L 2224/48227; H01L 2224/48247

(57) ABSTRACT

A package for use with an integrated circuit having a contact pad is provided. The package includes an enclosure portion; a package pin for external connection; and a protective element coupled between the contact pad and the package pin. The protective element is operable in a first state or a second state. In the first state the protective element passes a current between the contact pad and the package pin. When the current is above a threshold value the protective element changes from the first state to the second state to prevent the current from flowing between the contact pad and the package pin.

### CROSS-REFERENCE TO RELATED APPLICATION

The present application claims the benefit of U.S. Patent Application No. 63/484,297, titled “BOND-WIRE FOR BATTERY MANAGEMENT SYSTEM PROTECTION” and filed on Feb. 10, 2023, which is hereby incorporated by reference in its entirety.

### TECHNICAL FIELD

The present disclosure relates to a package for use with an integrated circuit and in particular to a package comprising a protective element to prevent damage to an external circuit. The present disclosure also relates to a circuit assembly provided with the package and the integrated circuit.

### BACKGROUND

For systems which contain internal circuits located on an integrated circuit chip, the internal circuits are often connected to external circuitry via a package pin. The package pin provides a metal route between the external circuit and the integrated circuit or die. A contact pad is provided at the surface of the internal circuit/die as a means for connection to the internal circuitry of the integrated circuit/die. The package pin may be used for connection to a printed circuit board (PCB). The external circuitry and/or power sources that can be used in such a system may include a series of battery cells.

Upon occurrence of a fault or physical damage to the internal circuitry, or of an error in the operation of the internal circuits, a high current may surge through the package. This may result in components of the external circuit being damaged or burned. Therefore, a protective circuit is needed. Solutions that have been implemented include using an external fuse to interrupt the surge of high current, however this solution is slow and expensive.

It is an object of the disclosure to address one or more of the above-mentioned limitations.

### SUMMARY

According to a first aspect of the disclosure, there is provided a package for use with an integrated circuit having a contact pad, the package comprising: an enclosure portion; a package pin for external connection; and a protective element coupled between the contact pad and the package pin, the protective element being operable in a first state or a second state; wherein in the first state the protective element is configured to pass a current between the contact pad and the package pin, and wherein when the current is above a threshold value the protective element is configured to change from the first state to the second state to prevent the current from flowing between the contact pad and the package pin.

Optionally, wherein in the first state the protective element has a low impedance to allow current flow.

Optionally, wherein in the second state the protective element has a high impedance to prevent current flow.

For instance, in the second state the protective element may break open or separate.

Optionally, the protective element comprises a bond wire.

Optionally, wherein the bond wire is made of a material configured to change its impedance upon a temperature change.

Optionally, wherein the material is a metallic material or a metal alloy material.

Optionally, wherein the material comprises at least one of Copper, Gold and Aluminium.

Optionally, wherein when the current is above the threshold value, the bond wire liquifies, hence increasing the impedance of the bond wire.

Optionally, wherein the bond wire has a geometry which defines the threshold value at which the bond wire changes from the first state to the second state.

Optionally, wherein the bond wire extends between a first end connectable to the contact pad of the integrated circuit and a second end connectable to the package pin.

Optionally, wherein the bond wire has a central portion provided between two tapered outer portions, the central portion having a central diameter smaller than an outer diameter of the outer portions.

Optionally, wherein the enclosure portion is made of plastic, ceramic, or metal or a combination of these materials.

According to a second aspect of the disclosure there is provided a circuit assembly comprising the package according to the first aspect connected to an integrated circuit.

Optionally, wherein the integrated circuit comprises an internal circuit.

According to a third aspect of the disclosure there is provided a system comprising the circuit assembly according to the second aspect, coupled to an external circuit.

Optionally, wherein the external circuit comprises a battery cell circuit to form a battery cell charging system.

### DESCRIPTION OF DRAWINGS

The disclosure is described in further detail below by way of example and with reference to the accompanying drawings, in which:

FIG. 1A is a diagram of a circuit assembly according to the present disclosure;

FIG. 1B is a cross sectional view of a package for use with an integrated circuit according to the present disclosure;

FIG. 2 is a table showing the melting temperatures of various materials that can be used in as protective elements;

FIG. 3A is a cross sectional view of an example embodiment of a protective element;

FIG. 3B is a cross sectional view of another example embodiment of a protective element;

FIG. 4 is a system comprising the circuit assembly of FIG. 1A coupled to an external circuit; and

FIG. 5 is a diagram of a battery cell charging system.

### DETAILED DESCRIPTION

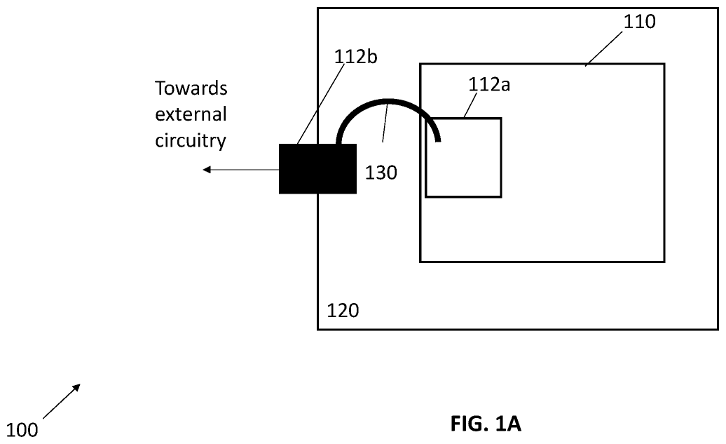

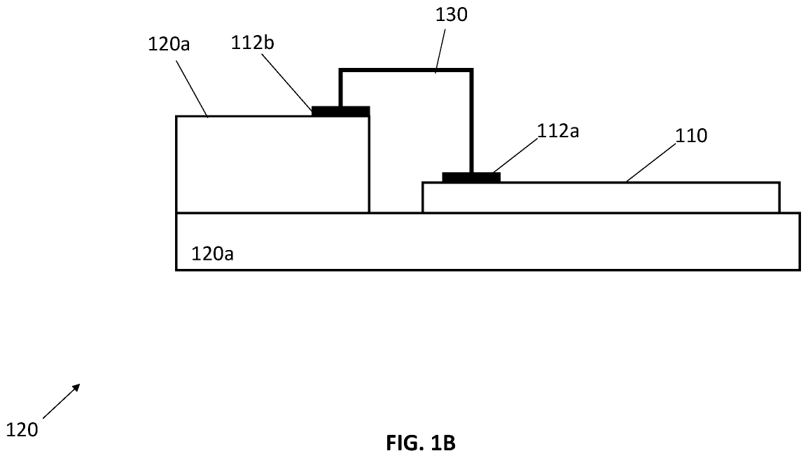

FIG. 1A is a diagram of a circuit assembly 100 according to the present disclosure. The circuit assembly 100 comprises a package 120 for use with an integrated circuit also referred to as die 110. The die 110 comprises a contact pad 112a. The package 120 comprises a package pin 112b for external connection. The protective element 130 is connected between the contact pad 112a and the package pin 112b. Therefore, the protective element 130 couples the die 110 to an external circuitry (not shown) via the package pin 112b.

The contact pad 112a could be, for example, a bond pad integrated onto the die 110 itself. A bond pad may be formed by a relatively large metal landing area on the die or integrated circuit 110 where a connecting element, such as the protective element 130, can connect to the internal circuitry of the die 110. The contact pad 112a could be made from, for example, of aluminium or copper. The die or integrated circuit 110 can comprise a variety of internal circuits. For example, it could comprise at least one of a measurement circuit, a memory circuit or a control circuit. The package pin 112b provides a path for connecting an external circuit, such as a printed circuit board, to the integrated circuit or die 110.

FIG. 1B is a cross-sectional view of the package 120 for use with a die or integrated circuit 110. The same reference numeral are used to refer to the same components as in FIG. 1A. The package 120 comprises an enclosure portion 120a which provides protection to the die 110. The enclosure portion 120a can be formed from, for example, plastic, ceramic, or metals.

The protective element 130 is operable in two states: a first state also referred to as a normal state and a second state, also referred to as a protective state. When a current is applied to the circuit assembly 100, the protective element 130 operates in the first state. During this normal state, the element 130 operates with a low impedance to allow the current to flow between the die 110 and the package pin 112b via the contact pad 112a. If a current greater than a threshold value, also referred to as a fault current, passes through the protective element 130, then the protective element changes from the first state to the second state. In the protective state, the protective element 130 opens and operates at a high impedance to prevent the current from flowing between the die 110 and the package pin 112b.

In the case of a fault occurring in the internal circuitry located in the die 110, a high, fault current may be generated and flow through the circuit assembly 100. The fault could be, for example, physical damage to or an operational error of the internal circuitry. The protective element 130 is designed to prevent a current above a threshold value from being delivered to the external circuitry via the package pin 112b. The threshold value or threshold current is determined by the properties of the protective element 130.

The protective element 130 could be, for example, a bond wire. The bond wire 130 may be implemented as a metallic compound that is configured to change its impedance upon a change in temperature. During the first state, the bond wire has a low impedance as the metallic compound has a high conductivity. Therefore, during normal operation of the circuit assembly 100 the bond wire does not have a significant impact on the current flow. The metallic compound, also referred to as a fuse element, has a thermal impedance and a melting temperature which dictate the minimum threshold value of current, also known as the fusing current, at which the fuse element begins to liquify due to the increase in temperature. When a fault current greater than the fusing current passes through the bond wire 130, the metallic compound begins to melt, separate and eventually opens or break thus increasing the impedance of the bond wire. This prevents the fault current from flowing through the circuit assembly 100 and the bond wire 130 is operating in the second state (protective state). The bond wire 130 can be adapted for different circuit uses as the threshold value can be adapted through the properties of the bond wire. The bond wire 130 is coupled to the contact pad 112a and the package pin 112b by means of a bonding operation, for example, ball bonding or wedge bonding.

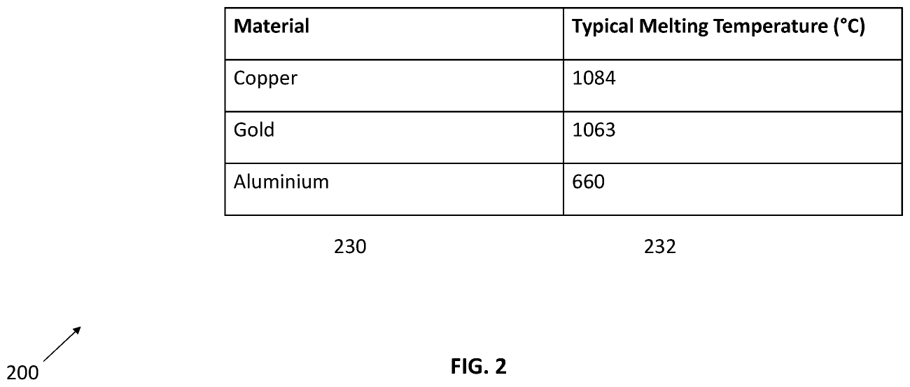

FIG. 2 shows a table 200 of different metallic compounds that can be used in the bond wire 230 and the typical temperature at which these compounds melt 232. This table shows an example selection of metallic compounds that could be used and is not an exhaustive list. Metallic compounds with a higher melting point temperature can sustain higher currents. Therefore, materials like gold and copper can be adapted for high current uses. However, lower melting point metallic compounds like aluminium can also be used. Choosing the right metallic compound is the primary factor when designing a bond wire 130 for use as a protective element in a circuit package. Other factors, including how the bond wire 130 is shaped, can also change the threshold value at which the bond wire changes operational states.

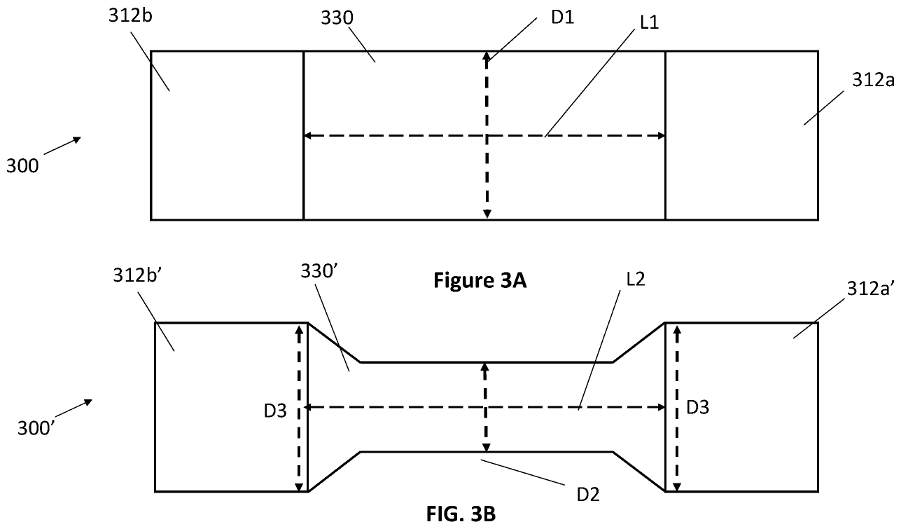

FIG. 3A is a cross sectional view of an exemplary bond wire for use in the circuit assembly of FIG. 1a. The bond wire 330 is coupled between a contact pad 312a and a package pin 312b. The bond wire 330 has a diameter D1 and a length L1. The diameter D1 of the bond wire 330 and the material define the current density that the wire can sustain without melting. This is an important factor for determining the threshold value of current that can be sustained by the bond wire. A larger diameter D1 will require a higher fault current to heat the wire beyond its melting temperature.

FIG. 3B is a cross sectional view of another exemplary bond wire for use in the circuit package of FIG. 1. The bond wire 330′ is coupled between the two contact pads 312a′ and 312b′. The bond wire 330′ has a length L2 extending between the contact pads 312a′ and 312b′ forming three portions: a central portion and two tapered outer portions. The central portion has a diameter D2, smaller than the diameter D3 at each end of the bond wire.

The compression of the bond wire 330′ provided at its central portion reduces the threshold value of current required for the bond wire 130 to melt and separate. The compression or crimping of the bond wire can be performed during the manufacturing process when the wire is fed into a bonder. The preferable place to crimp the bond wire 130 is at the thermal center of the wire. The thermal center is the point in the wire where the temperature will spike when a fault occurs in the internal circuitry and is dependent on the design of the circuit assembly 100. The contact pad 112a and package pin 112b provide thermal sinks, and during a fault event, heat will flow out of both of these components. If the heat flow out of the contact pad 112a is equal to that out of the package pin 112b then, the thermal center will be located at the mechanical center point of the bond wire 130. However, if the heat flow is unbalanced, the thermal center will shift.

Another property of the bond wire 130 that affects the threshold value at which the protective element changes operational states is the length of the wire. The physical process that causes the melting of the bond wire 130 when a fault current greater than the threshold value passes through the circuit assembly 100 is internal joule heating. The internal energy of the bond wire 130 increases with the increase of current causing the electrons to collide more frequently. This results in an increase in the heat of the bond wire 130 causing it to liquify. Bond wires with a longer length have an increased thermal impedance due to the longer path length that the internal energy to dissipate along. Therefore, the longer the wire the lower the threshold value.

Any one of the metallic compound, diameter or length of the bond wire 130, or a combination of the three properties, can be designed such that the protective element is best adapted for a given circuit assembly 100.

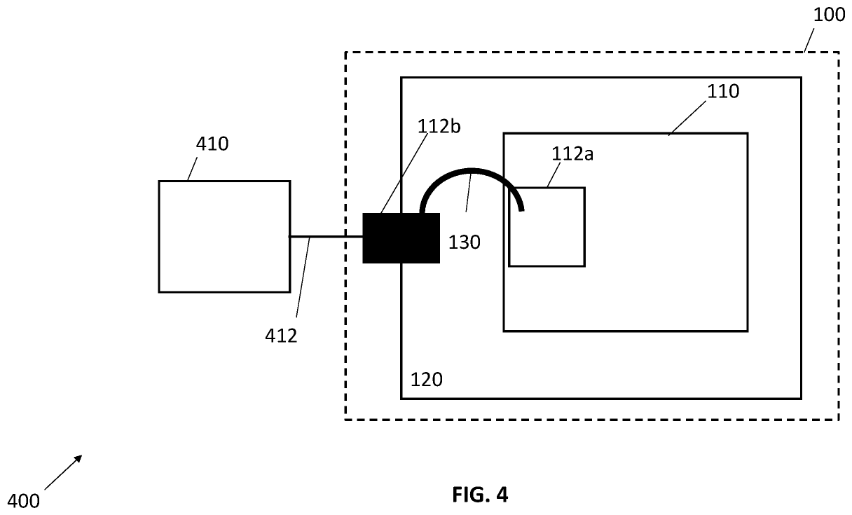

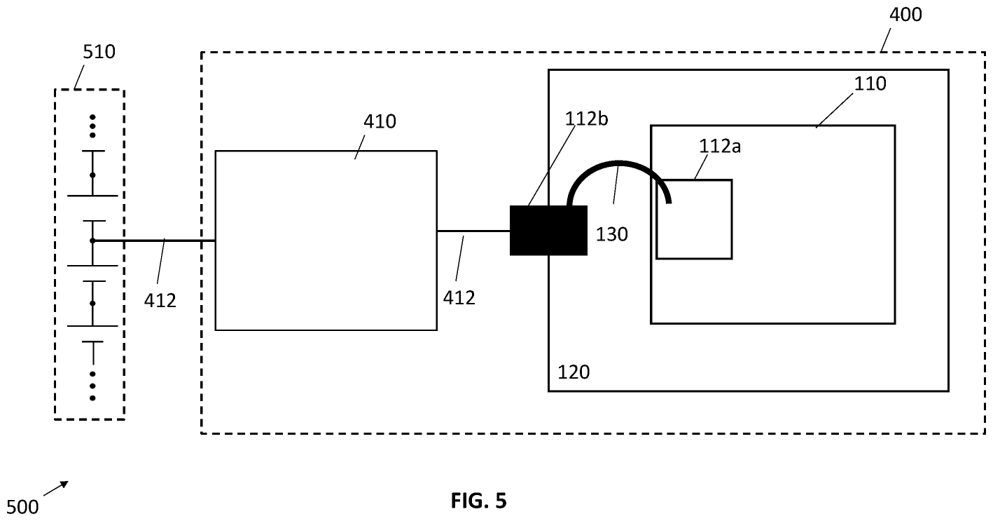

FIG. 4 is a diagram of a system 400 within which the circuit assembly 100 can be implemented. The same reference numerals have been used to describe the circuit package of FIGS. 1A and 1B. The system 400 shows the circuit assembly 100 coupled to an external circuit 410 via the package pin 112b and a connecting wire 412. The external circuit 410 could be, for example, a resistor bank or a computer control system.

As explained above, the protective element 130 has an adaptive impedance. The impedance of the protective element 130 changes in response to the current flowing through it. In normal circuit operation, the protective element 130 operates in the first state with a low impedance and does not have a significant impact on the way the current flows between the internal and external circuits. The normal mode of operation for the system 400 is characterized by a level of current flowing into and out of the internal circuits. The level of acceptable current is dependent on the exact characteristics of the system 400.

When a fault condition occurs in the internal circuit located in the die 110, such as an error in the way the internal circuit operates or physical damage to the circuit, the current flowing through protective element 130 may exceed the threshold value. The protective element 130 then changes to the second state and opens or operates with a higher impedance level. The increase in impedance of the protective element 130 will prevent the high current from flowing into the external circuit 410, hence protecting any electronic components in the external circuit from being damaged.

FIG. 5 is a diagram of a battery cell charging system. The system 500 comprises a series of battery cells 510 coupled to the system 400 of FIG. 4 via a connecting wire 412.

A skilled person will appreciate that variations of the disclosed arrangements are possible without departing from the disclosure. Accordingly, the above description of the specific embodiments is made by way of example only and not for the purposes of limitation. It will be clear to the skilled person that minor modifications may be made without significant changes to the operation described.

What is claimed is:

1. A package for use with an integrated circuit having a contact pad, the package comprising:
an enclosure portion;
a package pin for external connection; and
a protective element coupled between the contact pad and the package pin, the protective element being operable in a first state or a second state;
wherein in the first state the protective element is configured to pass a current between the contact pad and the package pin, and wherein when the current is above a threshold value the protective element is configured to change from the first state to the second state to prevent the current from flowing between the contact pad and the package pin.

2. The package as claimed in claim 1, wherein in the first state the protective element has a low impedance to allow current flow.

3. The package as claimed in claim 2, wherein in the second state the protective element has a high impedance to prevent current flow.

4. The package as claimed in claim 3, wherein the protective element comprises a bond wire.

5. The package as claimed in claim 4, wherein the bond wire is made of a material configured to change its impedance upon a temperature change.

6. The package as claimed in claim 5, wherein the material is a metallic material or a metal alloy material.

7. The package as claimed in claim 6, wherein the material comprises at least one of Copper, Gold and Aluminium.

8. The package as claimed in claim 7, wherein when the current is above the threshold value, the bond wire liquifies, hence increasing the impedance of the bond wire.

9. The package as claimed in claim 5, wherein the bond wire has a geometry which defines the threshold value at which the bond wire changes from the first state to the second state.

10. The package as claimed in claim 9, wherein the bond wire extends between a first end connectable to the contact pad of the integrated circuit and a second end connectable to the package pin.

11. The package as claimed in claim 10, wherein the bond wire has a central portion provided between two tapered outer portions, the central portion having a central diameter smaller than an outer diameter of the outer portions.

12. The package as claimed in claim 1 wherein the enclosure portion is made of plastic, ceramic, or metal or a combination of these materials.

13. A circuit assembly comprising the package as claimed in claim 1 connected to an integrated circuit.

14. The circuit assembly as claimed in claim 13, wherein the integrated circuit comprises an internal circuit.

15. A system comprising the circuit assembly as claimed in claim 13, coupled to an external circuit.

16. The system as claimed in claim 15, wherein the external circuit comprises a battery cell circuit to form a battery cell charging system.
